(19) United States
(12) Patent Application Publication
(10) Pub. No.: US 2003/0013312 A1
(43) Pub. Date: Jan. 16, 2003

(54) Method of reducing particle density in a cool down chamber

(76) Inventors: Hougong Wang, Pleasanton, CA (US); Ken Kaung K. Lai, Milpitas, CA (US); Anzhong Chang, San Jose, CA (US); Xiaoxiong Yuan, Cupertino, CA (US); Be V. Vo, Santa Clara, CA (US)

Correspondence Address: APPLIED MATERIALS, INC., 2881 SCOTT BLVD. M/S 2061, SANTA CLARA, CA, 95050, US

(21) Appl. No.: 09/903,218

(22) Filed: Jul. 10, 2001

(51) Int. Cl. H01L 21/302; H01L 21/461

(52) U.S. Cl. 438/706

(57) ABSTRACT

The present invention relates to a method and apparatus for removing particles from substrates undergoing processing in a semiconductor processing system. In the method according to the present invention, semiconductor wafers are placed in a vacuum chamber and gas is injected over the semiconductor wafer to dislodge and remove contaminant particles. The gas is provided by a gas injector affixed to the side of the vacuum chamber opposite the entry point of a wafer. In a preferred embodiment, the gas injector is oriented in the same horizontal plane as the robot arm used to place and remove wafers from the chamber.

### BACKGROUND OF THE INVENTION

Field of the Invention

The present invention relates to a method and apparatus for reducing particle contamination on a semiconductor wafer in a cool down chamber. In particular, the present invention relates to a method and apparatus for introducing gas into a cool down chamber to remove contaminant particles present on a semiconductor wafer.

### DISCUSSION OF THE BACKGROUND

In the semiconductor arts, semiconductor wafers or substrates are processed in individual chambers which are generally part of a larger cluster platform having multiple chambers. A typical semiconductor processing apparatus is shown in FIG. 1. As shown in FIG. 1, a plurality of process chambers (5, 6, 7, and 8) are arranged around a central processing station, or transfer chamber, which includes a robot arm 1 for moving a semiconductor wafer 2 between the process chambers 5-8. Each of these process chambers may perform different processes. For example, one process chamber may perform chemical vapor deposition (CVD) on a wafer while another chamber may perform an etching process. Two load lock chambers 3 and 4 include a plurality of slots (10 and 11 respectively) for holding numerous semiconductor wafers. A multiple slot cooling chamber 13 includes a plurality of slots 14 into which wafers may be stored for cooling between processing steps or after processing is completed. An optional cooling gas generator 15 may be coupled to the multiple slot cooling chamber 13 to provide a cooling gas to increase the cooling rate. A process controller 12 may be used to control the timing and movement of wafers through the various process chambers to effect the desired process steps on each wafer.

In particular, in the process steps associated with the manufacture of semiconductor wafers, process controller 12 causes robot arm 1 to remove a wafer 2 from a load lock chamber (3 or 4), optionally orient the wafer 2 in chamber 9, and move the wafer 2 to one or more of the process chambers 5-8 and cooling chamber 13 according to a desired “recipe” for the wafer. When the desired “recipe” has been carried out, the robot arm 1 orients the processed wafer in the multi-slot cool down chamber 13 to cool the wafer 2 before it is returned to the load lock chamber 13.

When the semiconductor wafer is properly oriented in the first process chamber, a reactant gas is introduced through a gas port. An excitation source (not shown) is coupled to the process chamber to generate a plasma that includes ions and radicals from the reactant gas, such as, for example, oxygen ions and radicals, that react with the semiconductor wafer. The excitation energy source may be a radio frequency (“RF”) field. In the alternative, the excitation energy source may be a microwave cavity and a microwave generator that provides a microwave field to the microwave cavity.

One major source of particle contamination of the semiconductor wafers is from incomplete reactions that occur in the plasma as RF power is increased to full power. For example, in the deposition of a silicon oxide layer, a plasma is formed from a process gas released into the processing chamber by applying RF power to the process chamber. In known prior art processes, the process gas is introduced into the process chamber and then RF power is applied. Although it only takes a few seconds for RF power to reach full power, reactions take place during that period of partial power which tend to be incomplete. As a result, particles are formed in the plasma.

These contaminant particles present in the process chamber are suspended in the plasma above the semiconductor substrate due to electrostatic interactions. At the end of the processing cycle, the forces that suspend the particles dissipate, and the particles fall out of the plasma and land on the semiconductor surface, thereby contaminating the semiconductor wafer.

Particles can also be introduced into the process chamber with the reactant gas or purge gas injected by the gas port, by the physical transfer of the wafer to and from the different processing chambers, or by manufacturing personnel handling the wafers. Some contaminants present on semiconductor wafers are particles or films generated from condensed organic vapors, solvent residues, photoresist, or metal oxide components.

Another major source of particle contamination is from the process chamber itself. Small particles reside on the chamber walls which are microscopically rough. The relatively strong burst of gas introduced into the process chamber removes these particles from the walls. These contaminants may then be deposited on the semiconductor wafer.

In semiconductor processing, a large percentage of yield losses can be attributed to contamination by particles and of the exposed film. Typical problems and detrimental effects caused by particle or film contaminants on a semiconductor wafer are poor adhesion of deposited layers or poor etching of the underlying material. The electrical properties and the stability of devices built on the semiconductor substrate may also be seriously affected by contaminants. For instance, contaminant particles can cause a device to fail by creating unpredictable surface topography, by inducing leakage current through the insulating layer, or otherwise reducing the lifetime of the device.

In addition, when the number of particles located on a clean wafer consistently exceeds 20 particles, the cool down chamber must be cleaned. Generally, a cool down chamber must be cleaned once a week, which results in a reduction in the throughput, or number of wafers that can be processed.

It is generally accepted by those of skill in the art that a particle contaminant that exceeds one-fifth to one-half of a minimum feature size on a device has the potential of causing a fatal defect which causes the device to fail completely. A defect of smaller size may also be fatal if it falls in a critical area. Thus, there exists a need for a method and apparatus for efficiently removing contaminant particles from the surface of a semiconductor wafer.

### SUMMARY OF THE INVENTION

One aspect of the present invention includes a method and apparatus for reducing particle density on a semiconductor wafer.

Another aspect of the present invention includes a gas flow injector which introduces gas into a multi-slot chamber to remove contaminant particles located on the surface of a semiconductor wafer located within slots in the chamber.

With the foregoing and other objects, advantages and features of the invention that will become hereinafter apparent, the nature of the invention may be more clearly understood by reference to the following detailed description of the preferred embodiments of the invention and to the appended claims.

### BRIEF DESCRIPTION OF THE DRAWINGS

FIG. 1 illustrates a conventional semiconductor processing apparatus.

FIG. 2 illustrates a multi-slot cool down chamber.

FIG. 3 illustrates a multi-slot cool down chamber with the gas injector according to the present invention.

FIG. 4 illustrates the positioning of the gas injector relative to a semiconductor wafer in a cool down chamber.

FIG. 5 is a graphical illustration of the number of added particles present on processed wafers for over 10,000 wafers.

### DESCRIPTION OF THE PREFERRED EMBODIMENTS

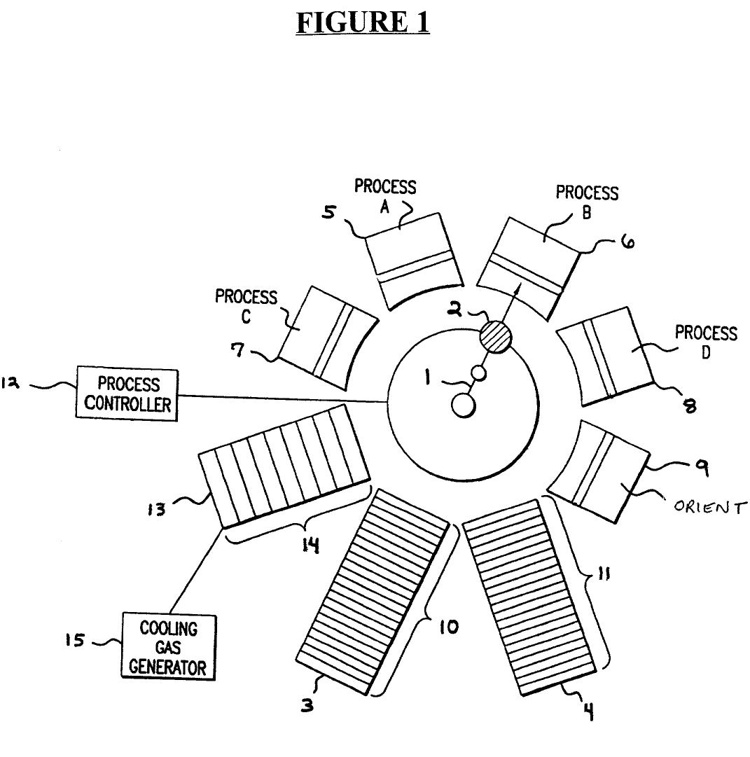

In semiconductor fabrication, semiconductor wafers are typically processed in individual chambers which are generally part of a larger cluster platform having multiple chambers. FIG. 1 shows a typical arrangement of a single-wafer, multi-chamber apparatus for semiconductor fabrication. As shown in FIG. 1, a plurality of process chambers (5, 6, 7, and 8) are arranged around a central processing station, or transfer chamber, which includes a robot arm 1 for moving a semiconductor wafer 2 through the various stages of fabrication. In particular, the process controller 12 causes the robot arm 1 to remove a semiconductor wafer from a load lock chamber (3 or 4) and move the semiconductor wafer through one or more process chambers 5, 6, 7, or 8 in a predetermined pattern. In addition to the process chambers, an orientation chamber 9 can be included to orient the wafer prior to processing. Orientation generally entails locating the center and any flats, orientation marks, or notches of a wafer inserted into the chamber, correctly rotationally aligning the wafer in the orientation chamber, and then passing the center point information to process controller 12 so that robot arm 1 can properly center the wafer upon insertion into one of the process chambers. Additionally, a cool down chamber 13 may be used to allow wafers to cool before being placed in the wafer cassette in the entry/exit load lock chamber.

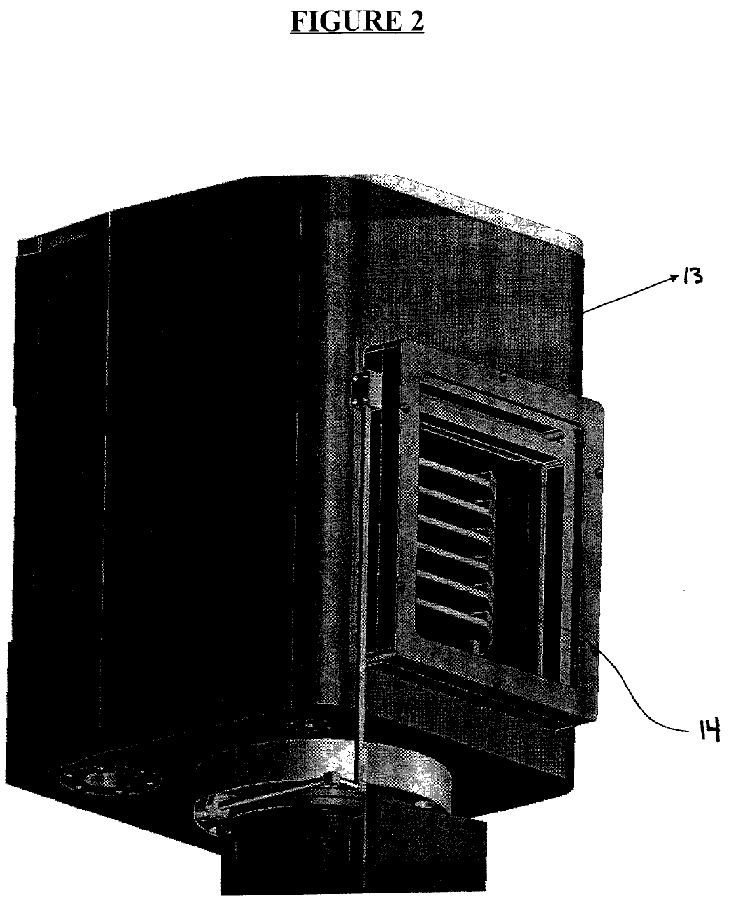

The cool down chamber 13 contains a plurality of slots 14 into which semiconductor wafers may be inserted. An elevator mechanism (not shown) is used to move the slots 14 up and down in order to position one of the slots 14 in alignment with a wafer 2, on a robot arm 1 to receive (or dispense) the wafer 2. An optional cooling gas generator 15 may be coupled to the multi-slot cool down chamber 13 to provide a cooling gas which increases the cooling rate over that attainable by radiative cooling. Process controller 12 controls the movement of wafers through the predetermined process steps and into an available slot in the cool down chamber 13. Since more than one slot is provided in the cool down chamber 13, more wafers can be cooled at the same time. A typical multi-slot cool down chamber is illustrated in FIG. 2.

Particle contamination on a semiconductor wafer can come from a variety of sources. As discussed in the background section of this application, particles can be generated during plasma formation, introduced with the gas injected by the gas port, introduced by transferring the wafer to and from the different processing chambers, or introduced by the handling of manufacturing personnel. Some contaminants are particles or films generated from condensed organic vapors, solvent residues, photoresist, or metal oxide components.

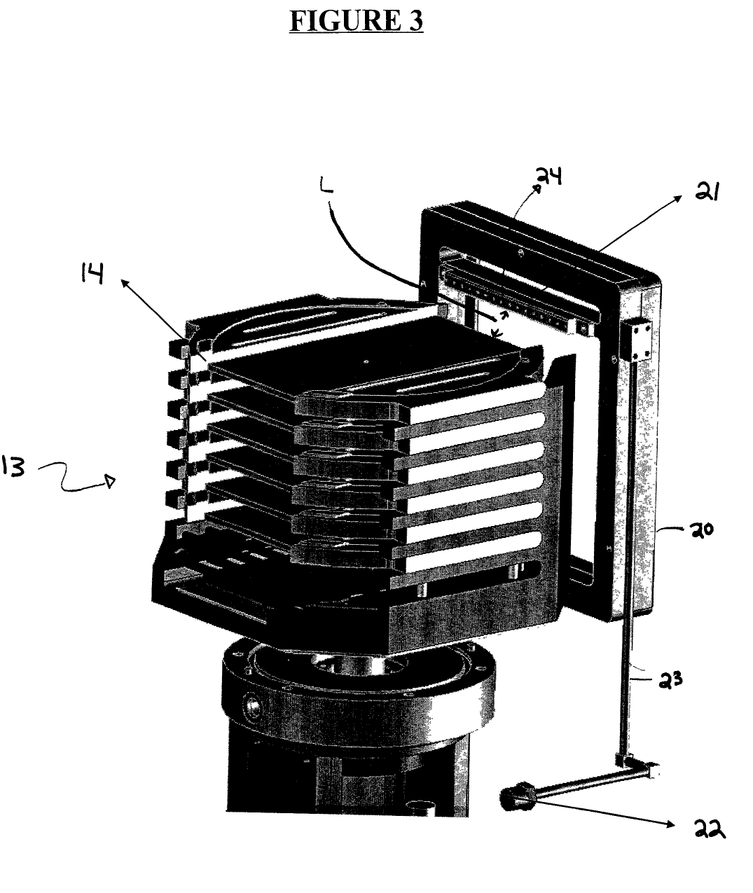

In one embodiment of the present invention, contaminant particles are removed from the surface of semiconductor wafers in the cool down chamber 13. A multi-slot cool down chamber with a gas injector according to the present invention is illustrated in FIG. 3. As shown in FIG. 3, a vertical support 20 is affixed to one side of the cool down chamber 13. In particular, support 20 is located on the side of the cool down chamber opposite the face of the cool down chamber where it is attached to the transfer chamber. A gas injector 21 is connected to vertical support 20 such that the gas injector 21 is located in, or nearly in, the same plane as one of slots 14. Gas inlet 22 and tubing 23 are attached to gas injector 21 to supply gas, such as nitrogen, helium, or argon to gas injector 21. It should be noted that the particle reducing apparatus described above can be affixed to other locations in a semiconductor processing apparatus such as entry load lock, etc.

Typically, slots 14 are elevated or lowered in order to place an empty slot slightly below the plane of a wafer on the robot arm 1. The robot arm then places a semiconductor wafer in the space above the empty slot in the cool down chamber. The slot is moved upwardly to lift the wafer off the robot blade, after which the robot blade retracts. Gas flows through tubing 23 and into gas injector 21, where it exits through injector holes 24 into the slot of the cool down chamber and over the semiconductor wafer contained therein, thereby dislodging contaminant particles. The gas stream containing the particles then flows outwardly of the cool down chamber and into the transfer chamber which is directly attached to the cool down chamber. Consequently, both the transfer chamber and cool down chamber are in a vacuum. The gas and contaminant particles are then pumped out through an exhaust system. To maximize the efficiency of the particle removal, the semiconductor wafer can receive an injection of gas when it first enters the slot and again before it exits the slot.

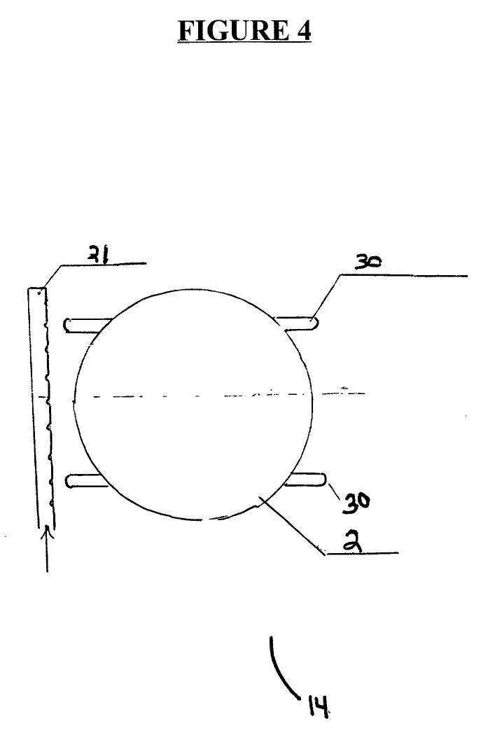

The orientation of the semiconductor wafer relative to the gas injector is shown in FIG. 4. The gas injector 21 is located in substantially the same horizontal plane as the semiconductor wafer 2 when the wafer is received in the slot from the robot arm 1 to ensure that semiconductor wafer 2 receives a substantial flow of gas from the gas injector 21 to dislodge any contaminant particles located on the semiconductor wafer. Additionally, the spacing between the wafer and the injector is minimized to maximize the gas flow over the wafer. If the gas injector is located far away from the slots, most of the gas exiting through the injector holes escapes through the upper part of the cool down chamber and does not reach the semiconductor wafer. As a result, the gas injector is preferably located close to the slots so that when the gas is injected through the injector holes on the gas injector, most of the gas goes through the slot 14 and around the semiconductor wafer 2. Preferably, the distance from the gas injector 21 and the slot 14 is from within 0.855 inches to within 2.565 inches. Additionally, the gas injector is preferably straight, as is shown in FIG. 4.

A mass flow controller uniformly controls the flow of gas through gas inlet 22 when the flow rate is greater than or equal to approximately 400 sccm, the minimum flow rate which ensures that gas flows from the cool down chamber to the transfer chamber and not from the transfer chamber to the cool down chamber. Preferably, the gas flow rate through the injector is greater than or equal to 2000 sccm during cleaning.

The injector holes in the tubing are preferably from less than 0.06 to less than 0.2 inches in diameter. A size of approximately 0.06 inches in diameter is most preferred. The injector holes may be horizontally aligned or offset relative to each other to effect a wider flow of air over the semiconductor wafer. Further, there may be more than one row of injector holes. The tube is generally formed of rubber, nylon, plastic, or metal, although any suitable material as determined by one of skill in the art can be used.

Each of the slots of the cool down chamber contain two supports 30, which can best be seen in FIG. 4. When the semiconductor wafer is placed into a slot in the cool down chamber, it is placed on supports 30. These supports are typically made of aluminum oxide, but other suitable materials would be easily identified by one of skill in the art. It is hypothesized that using a conductive support such as aluminum, any charged particles located on the backside of the semiconductor wafer would be neutralized and thus blown away more easily.

Having generally described this invention, a further understanding can be obtained by reference to certain specific examples which are provided herein for purposes of illustration only and are not intended to be limiting unless otherwise specified.

### Example 1

Gas Flow Uniformity Through Injector Holes

To determine the preferred gas flow rate for use in the particle reduction apparatus of the present invention, flow simulations were conducted. In the simulations, the gas injector according to the present invention contained 16 evenly 110 spaced injector holes. In the instant example, the holes were 12.5 mm apart. Five separate cases were studied by varying the injector hole diameter and gas flow rate as shown in the Table 1 set forth below.

TABLE 1

| | Hole Diameter | Flow Rate | |
|---|---|---|---|
| Case | [inch] | [sccm] | R_Inlet_Flow |
| Case 1 | 0.06 | 2000 | 1.04 |
| Case 2 | 0.012 | 2000 | 1 |
| Case 3 | 0.18 | 2000 | 18.6 |
| Case 4 | 0.06 | 400 | 1.35 |
| Case 5 | 0.06 | 6000 | 1.01 |

$* R\_Inlet \_Flow = \frac{\begin{matrix}Maximum flow rate through the \\ first injector hole\end{matrix} }{\begin{matrix}Minimum flow rate through the \\ last injector hole\end{matrix}}$

From this data, it was determined that gas is most uniformly distributed through a gas injector containing 16 injector holes when the flow rate is not less than 2000 sccm and the injector hole diameter is not more than 0.06 inches.

### Example 2

Determination of the Quantity of Gas that Flows through the Slots between the Semiconductor Wafers

To determine the amount of gas that flows through the slots between the semiconductor wafers, flow simulations were conducted. In the flow simulations, the injector hole diameter, gas flow rate, and distance L from the gas injector and the slot of the cool down chamber were varied in 7 separate cases as shown in Table 2 set forth below.

TABLE 2

| | Hole Diameter | Flow Rate | L | R_Top_Flow* |
|---|---|---|---|---|
| Case | [inch] | [sccm] | [inch] | [%] |
| Case 1 | 0.06 | 2000 | 0.855 | 64.1 |
| Case 2 | 0.18 | 2000 | 0.855 | 65.8 |
| Case 3 | 0.06 | 400 | 0.855 | 68.7 |
| Case 4 | 0.06 | 6000 | 0.855 | 52.1 |
| Case 5 | 0.06 | 2000 | 0.171 | 59.2 |
| Case 6 | 0.06 | 2000 | 2.565 | 74.5 |

$* R\_Top \_Flow = \frac{Gas flow through upper part of cool down chamber }{Total gas flow through injector holes}$

From this data, it was concluded that the ratio of gas which escapes into the upper part of the cool down chamber and which does not pass through the slots of the cool down chamber decreases as the distance L between the gas injector and the slot of the cool down chamber decreases, the total flow rate increases, or the injector hole diameter decreases.

### Example 3

Determination of the Effectiveness of the Particle Reducing Apparatus of the Present Invention

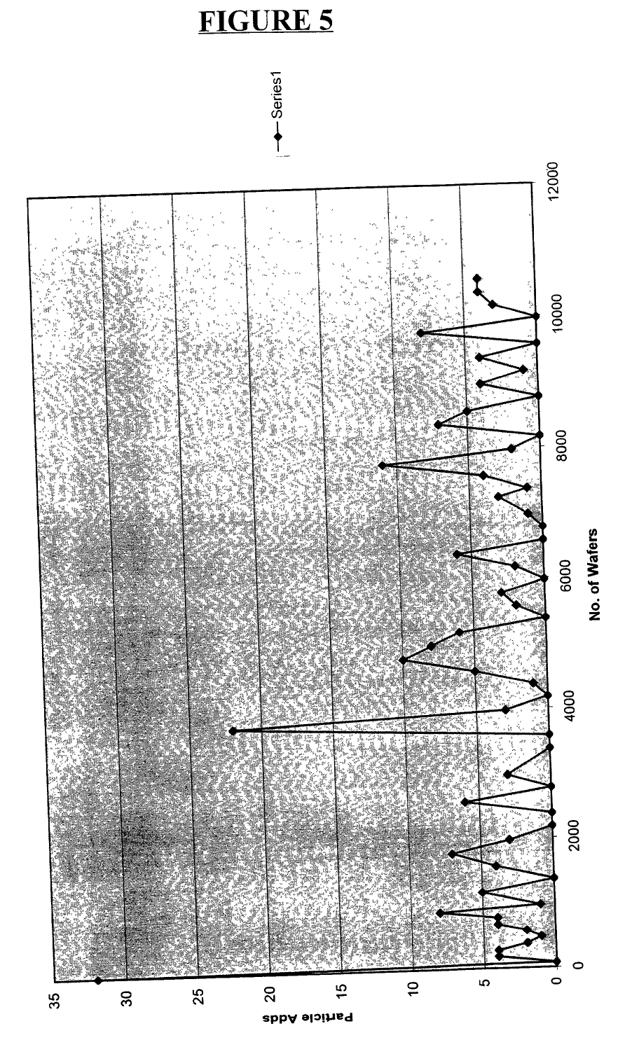

In order to determine the effectiveness of the particle reducing apparatus of the present invention, the following experiment was conducted. First, cool down chamber and particle reducing apparatus of the present invention were cleaned. Clean wafers were then introduced and processed, and the particles were removed in the cool down chamber by the particle reducing apparatus of the present invention. Next, the processed wafers were removed and the number of particles present on the semiconductor wafers was counted. FIG. 5 is a graphical illustration of the number of added particles present on each of the processed wafers for over 10,000 wafers. It can be seen that in over 10,000 wafers processed using the particle reducing apparatus of the present invention, the average particle addition to the wafer is less than 4. As a comparison, when the particle reducing apparatus of the present invention is not used, contaminant particles accumulate quickly on the semiconductor wafer (i.e., approximately 20-30 per week), thereby requiring that the chamber be cleaned once a week. Additionally, as shown in FIG. 5, if the particle reducing apparatus of the present invention is utilized, a minimum of 10,000 wafers can be processed without having to clean the cool down chamber and transfer chamber (e.g., a period of 1-2 months).

The invention of this application is described above both generically, and with regard to specific embodiments. A wide variety of alternatives known to those of ordinary skill in the art can be selected within the generic disclosure, and examples are not to be interpreted as limiting, unless specifically so indicated. The invention is not otherwise limited, except for the recitation of the claims set forth below. All references cited herein are incorporated in their entirety.

What is claimed is:

1. A method for reducing particle contamination on a semiconductor wafer in a vacuum chamber comprising the steps of:
placing a processed semiconductor wafer into a vacuum chamber;
orienting at least a portion of said vacuum chamber so that said semiconductor wafer is substantially aligned with a gas injector in fluid connection with a tube which provides said gas for said gas injector; and
injecting a gas into said vacuum chamber so that said gas flows over said semiconductor wafer and dislodges at least a portion of particles from the surface of said semiconductor wafer.

2. The method of claim 1, wherein said vacuum chamber is a multi-slot cool down chamber containing a plurality of slots and said semiconductor wafer is located in one of said slots in said multi-slot cool down chamber.

3. The method of claim 2, wherein said gas injector is located on a side of said multi-slot cool down chamber opposite a transfer chamber.

4. The method of claim 3, wherein said gas injector contains injector holes through which said gas exits into said slot containing said semiconductor wafer.

5. The method of claim 4, wherein said gas injector is connected to a support affixed to a side of said multi-slot cool down chamber.

6. The method of claim 2, wherein said gas is selected from the group consisting of Ar, He and N₂.

7. The method of claim 1, wherein said tube is formed from a material selected from the group consisting of nylon, plastic, metal and rubber.

8. The method of claim 2, wherein said gas flows at a rate greater than or equal to 400 sccm.

9. The method of claim 8, wherein said rate is approximately 2000 sccm.

10. The method of claim 4, wherein said injector holes are less than 0.2 inches in diameter.

11. The method of claim 10, wherein said injector holes are approximately 0.06 inches in diameter.

12. The method of claim 2, wherein said gas injector is located at a distance of less than 2.565 inches from said slot.

13. The method of claim 12, wherein said gas injector is located at a distance of from approximately 0.855 inches.

14. The method of claim 2, wherein said gas is injected through said multi-slot cool down chamber and into said transfer chamber where said gas and said particles dislodged from the surface of said semiconductor wafer are evacuated through an exhaust system.

15. An apparatus for reducing particle density on a semiconductor wafer in a cool down chamber comprising:
a vacuum chamber;
a support affixed to a front side of said vacuum chamber;
a gas injector connected to said support; and
a tube in fluid connection with said gas injector to provide a gas to said gas injector;
wherein said gas injector is positioned to inject said gas into said vacuum chamber and over a semiconductor wafer when located therein, and dislodges at least a portion of contaminant particles from the surface of said semiconductor wafer.

16. The apparatus of claim 15, wherein said vacuum chamber is a multi-slot cool down chamber containing a plurality of slots and said semiconductor wafer is located in a slot in said multi-slot cool down chamber.

17. The apparatus of claim 16, further comprising a robot arm to place said semiconductor wafer in said slot of said cool down chamber, wherein said gas injector is oriented in the same plane as said robot arm.

18. The apparatus of claim 15, wherein said gas is selected from the group consisting of Ar, He and N₂.

19. The apparatus of claim 15, wherein said tube is formed from a material selected from the group consisting of nylon, rubber, plastic and metal.

20. The apparatus of claim 16, wherein said gas injector contains injector holes through which said gas exits into said slot.

21. The apparatus of claim 20, wherein said injector holes are less than 0.2 inches in diameter.

22. The apparatus of claim 21, wherein said injector holes are approximately 0.06 inches in diameter.

23. The apparatus of claim 17, wherein said gas injector is located at a distance of less than 2.565 inches from said slot.

24. The apparatus of claim 23, wherein said gas injector is located at a distance of approximately 0.855 inches from said slot.
